(19) United States
(12) Patent Application Publication
(10) Pub. No.: US 2011/0193204 A1
(43) Pub. Date: Aug. 11, 2011

(54) SEMICONDUCTOR DEVICE

(75) Inventor: Ki-Young KIM, Seongnam-si (KR)

(73) Assignee: HYNIX SEMICONDUCTOR INC., Icheon-si (KR)

(21) Appl. No.: 13/016,611

(22) Filed: Jan. 28, 2011

(30) Foreign Application Priority Data
Feb. 5, 2010 (KR) 10-2010-0010900

(51) Int. Cl. H01L 23/495; H01L 23/498

(52) U.S. Cl. 257/666; 257/737; 257/784; 257/E23.068; 257/E23.033

(57) ABSTRACT

A semiconductor package includes a substrate including a substrate body which has an upper surface and a lower surface facing away from the upper surface, first connection pads which are formed on the upper surface, and a second connection pad which is formed on the upper surface to be separated from the first connection pads, a semiconductor chip including first bonding pads and a second bonding pad, connection members connecting the first connection pads and the first bonding pads, and a resistor member connecting the second connection pad and the second bonding pad.

### CROSS-REFERENCE TO RELATED APPLICATIONS

The present application claims priority to Korean patent application number 10-2010-10900 filed on Feb. 5 2010, which is incorporated herein by reference in its entirety.

### BACKGROUND OF THE INVENTION

The present invention relates to a resistor-embedded semiconductor device.

In order to meet the trend of electronic products toward miniaturization and light weight, efforts are being made to reduce the area occupied by a resistor. As a part of the efforts, a resistor-embedded PCB (printed circuit board), in which a resistor is embedded in the PCB of a semiconductor device, has been disclosed in a known art.

However, in order to manufacture the resistor-embedded PCB, processes for depositing a material layer to be used as a resistor and etching the material layer are conducted in addition to usual processes for forming a PCB. Thus, manufacturing of the PCB may become complicated. Also, the characteristics of the PCB are likely to be changed due to poor adhesion force between the material layer to be used as the resistor and the layer constituting the PCB and the addition of the material layer to be used as the resistor, as a result of which the reliability of a semiconductor device is likely to be degraded.

### BRIEF SUMMARY OF THE INVENTION

An embodiment of the present invention is directed to a resistor-embedded semiconductor device which can minimize the difficulties in the manufacture of a semiconductor device and secure the reliability of the semiconductor device.

In an exemplary embodiment of the present invention, a semiconductor package includes a substrate including a substrate body which has an upper surface and a lower surface facing away from the upper surface, first connection pads which are formed on the upper surface, and a second connection pad which is formed on the upper surface to be separated from the first connection pads, a semiconductor chip including first bonding pads and a second bonding pad, connection members connecting the first connection pads and the first bonding pads; and a resistor member connecting the second connection pad and the second bonding pad.

The resistor member and the connection members may be formed as bonding wires or bumps.

In another exemplary embodiment of the present invention, a semiconductor package includes a substrate including a substrate body which has an upper surface and a lower surface facing away from the upper surface, first connection pads which are formed on the upper surface, and a second connection pad which is formed on the upper surface to be separated from the first connection pads, a semiconductor chip including first bonding pads and a second bonding pad, first connection members connecting the first connection pads and the first bonding pads, a first resistor member formed on the second connection pad, a second resistor member formed on the second bonding pad, and a second connection member connecting the first resistor member and the second resistor member.

The first resistor member and the second resistor member may be formed as bumps, and the first and second connection members may be formed as bonding wires.

In another exemplary embodiment of the present invention, a semiconductor device includes a first structural body having a first electrode pad, a second structural body having a second electrode pad, and a resistor module electrically connecting the first electrode pad and the second electrode pad and including a resistor member formed in at least a portion of the resistor module.

Each of the first structural body and the second structural body may include any one of a semiconductor device, a printed circuit board and a semiconductor package.

The semiconductor device may include any one selected among an image sensor, a memory semiconductor, a system semiconductor, a passive device, an active device, and a sensor semiconductor, and the printed circuit board may include any one selected among a module substrate, a package substrate, a main board, and a flexible substrate.

The resistor member may include at least any one selected from the group consisting of manganese (Mn), tin (Sn) and titanium (Ti).

The resistor module may further include a connection member which is formed in another portion of the resistor member and has specific resistance smaller than that of the resistor member.

Each of the connection member and the resistor member may include any one selected among a wire, a bump, and a solder ball.

The connection member may include at least any one selected from the group consisting of gold (Au), silver (Ag) and aluminum (Al).

The resistor member may be formed on the first electrode pad, and the connection member may electrically connect the resistor member and the second electrode pad.

The resistor member may be formed on the second electrode pad, and the connection member may electrically connect the resistor member and the first electrode pad.

The resistor member may include a first resistor member which is formed on the first electrode pad and a second resistor member which is formed on the second electrode pad, and the connection member may electrically connect the first resistor member and the second resistor member.

The resistor module may further include a connection pad which is formed on the first structural body or the second structural body, the connection member may electrically connect the first electrode pad and the connection pad, and the resistor member may electrically connect the connection pad and the second electrode pad.

The resistor module may further include a connection pad which is formed on the first structural body or the second structural body, the resistor member may electrically connect the first electrode pad and the connection pad, and the connection member may electrically connect the connection pad and the second electrode pad.

The connection member may include a first connection member which is formed on the first electrode pad and a second connection member which is formed on the second electrode pad, and the resistor member may electrically connect the first connection member and the second connection member.

### BRIEF DESCRIPTION OF THE DRAWINGS

FIG. 1 is a plan view illustrating a semiconductor device in accordance with an exemplary embodiment of the present invention.

FIG. 2 is a cross-sectional view taken along the line I-I′ of FIG. 1.

FIG. 3 is a plan view illustrating a semiconductor device in accordance with another exemplary embodiment of the present invention.

FIG. 4 is a cross-sectional view taken along the line II-II′ of FIG. 3.

FIG. 5 is a plan view illustrating a semiconductor device in accordance with another exemplary embodiment of the present invention.

FIG. 6 is a cross-sectional view taken along the line III-III′ of FIG. 5.

FIG. 7 is a plan view illustrating a semiconductor device in accordance with another exemplary embodiment of the present invention.

FIG. 8 is a cross-sectional view taken along the line IV-IV′ of FIG. 7.

FIG. 9 is a cross-sectional view illustrating a semiconductor device in accordance with another exemplary embodiment of the present invention.

FIG. 10 is a cross-sectional view illustrating a semiconductor device in accordance with another exemplary embodiment of the present invention.

FIG. 11 is a cross-sectional view illustrating a semiconductor device in accordance with another exemplary embodiment of the present invention.

FIG. 12 is a cross-sectional view illustrating a semiconductor device in accordance with another exemplary embodiment of the present invention.

FIG. 13 is a cross-sectional view illustrating a semiconductor device in accordance with another exemplary embodiment of the present invention.

### DESCRIPTION OF SPECIFIC EMBODIMENTS

Hereafter, specific embodiments of the present invention will be described in detail with reference to the accompanying drawings.

It is to be understood herein that the drawings are not necessarily to scale and in some instances proportions may have been exaggerated in order to more clearly depict certain features of the invention.

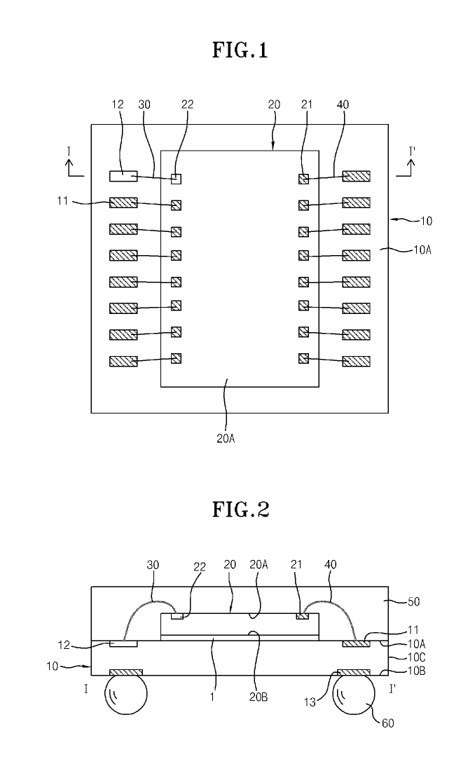

FIG. 1 is a plan view illustrating a semiconductor device in accordance with an exemplary embodiment of the present invention, and FIG. 2 is a cross-sectional view taken along the line I-I′ of FIG. 1.

Referring to FIGS. 1 and 2, the semiconductor device in accordance with the exemplary embodiment of the present invention includes a printed circuit board 10, a semiconductor chip 20, and a resistor module 30. In addition, the semiconductor device further includes connection parts 40, a mold part 50 and external connection terminals 60.

The printed circuit board 10 has a first surface 10A, a second surface 10B, and side surfaces 10C. The first surface 10A faces away from the second surface 10B, and the side surfaces 10C connect the first surface 10A and the second surface 10B.

The printed circuit board 10 includes first and second connection pads 11 and 12 and ball lands 13. The first connection pads 11 and the second connection pad 12 are formed on the first surface 10A of the printed circuit board 10. In this exemplary embodiment, the first connection pads 11 are formed adjacent to the edges of the first surface 10A, and the second connection pad 12 is formed to be separated from the first connection pads 11. The ball lands 13 are formed on the second surface 10B of the printed circuit board 10. While not shown in a drawing, the printed circuit board 10 may include circuit wiring lines which are formed on multiple layers in the printed circuit board 10 and conductive vias which connect the circuit wiring lines formed on different layers. The first and second connection pads 11 and 12 are electrically connected with the ball lands 13 by the circuit wiring lines and the conductive vias which are formed in the printed circuit board 10. The printed circuit board 10 may include any one selected among a module substrate, a package substrate, a main board, and a flexible substrate.

The semiconductor chip 20 is attached to the first surface 10A of the printed circuit board 10 with an adhesive member 1 inside the first and second connection pads 11 and 12.

The semiconductor chip 20 has a third surface 20A which faces away from the first surface 10A of the printed circuit board 10 and a fourth surface 20B which faces away from the third surface 20A. First bonding pads 21 and a second bonding pad 22 are formed on the third surface 20A of the semiconductor chip 20, and the fourth surface 20B of the semiconductor chip 20 is attached to the first surface 10A of the printed circuit board 10 with the adhesive member 1. The first bonding pads 21 correspond to the first connection pads 11 of the printed circuit board 10, and the second bonding pad 22 corresponds to the second connection pad 12 of the printed circuit board 10. In this exemplary embodiment, the first bonding pads 21 and the second bonding pad 22 are formed adjacent to the edges of the third surface 20A of the semiconductor chip 20. The semiconductor chip 20 may include any one selected among an image sensor, a memory semiconductor, a system semiconductor, a passive device, an active device, and a sensor semiconductor.

The resistor module 30 electrically connects the second connection pad 12 and the second bonding pad 22, and the connection parts 40 electrically connect the first connection pads 11 and the first bonding pads 21. In this exemplary embodiment, the resistor module 30 and the connection parts 40 are formed as wires.

The connection parts 40 may include at least any one selected from the group consisting of gold (Au), silver (Ag) and aluminum (Al).

In this exemplary embodiment, the resistor module 30 is formed of a resistor member which has specific resistance larger than that of the connection parts 40. For example, the resistor member may include at least any one selected from the group consisting of manganese (Mn), tin (Sn) and titanium (Ti).

The resistance value of the resistor module 30 may be controlled by changing the diameter and the length of the wire constituting the resistor module 30. In the case where the resistor module 30 should have a large resistance value, the wire constituting the resistor module 30 is formed to have a relatively small diameter or a long length. In the case where the resistor module 30 should have a small resistance value, the wire constituting the resistor module 30 is formed to have a relatively large diameter or a short length.

The mold part 50 seals the first surface 10A of the printed circuit board 10 including the semiconductor chip 20, and the external connection terminals 60 are mounted to the ball lands 13 which are formed on the second surface 10B of the printed circuit board 10.

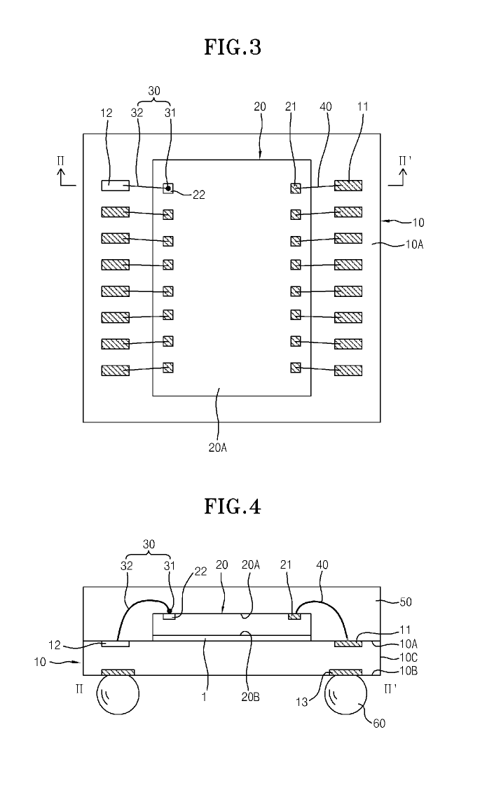

FIG. 3 is a plan view illustrating a semiconductor device in accordance with another exemplary embodiment of the present invention, and FIG. 4 is a cross-sectional view taken along the line II-II′ of FIG. 3.

The semiconductor device in accordance with this exemplary embodiment of the present invention has substantially the same construction as the semiconductor device in accordance with the exemplary embodiment described above with reference to FIGS. 1 and 2, except a resistor module 30. Accordingly, repeated descriptions for the same component elements will be omitted herein, and the same technical terms and the same reference numerals will be used to refer to the same component elements.

Referring to FIGS. 3 and 4, the semiconductor device in accordance with this exemplary embodiment of the present invention includes a printed circuit board 10, a semiconductor chip 20, and a resistor module 30. In addition, the semiconductor device may further include connection parts 40, a mold part 50 and external connection terminals 60.

In this exemplary embodiment, the resistor module 30 includes a resistor member 31 and a connection member 32.

The resistor member 31 is formed on a second bonding pad 22 of the semiconductor chip 20. In this exemplary embodiment, the resistor member 31 is formed as a bump or a solder ball. The connection member 32 electrically connects the resistor member 31 and a second connection pad 12 of the printed circuit board 10. In this exemplary embodiment, the connection member 32 is formed as a wire. The connection member 32 may be formed of the same material as the connection parts 40. For example, the connection member 32 may include at least any one selected from the group consisting of gold (Au), silver (Ag) and aluminum (Al).

The resistor member 31 is formed of a material which has specific resistance larger than that of the connection parts 40 and the connection member 32. For example, the resistor member 31 may include at least any one selected from the group consisting of manganese (Mn), tin (Sn) and titanium (Ti).

The resistance value of the resistor module 30 may be controlled by changing the diameter of the bump or the solder ball constituting the resistor member 31. In the case where the resistor module 30 should have a large resistance value, the bump or the solder ball constituting the resistor member 31 is formed to have a relatively small diameter. In the case where the resistor module 30 should have a small resistance value, the bump or the solder ball constituting the resistor member 31 is formed to have a relatively large diameter.

Although it was illustrated and explained in the this exemplary embodiment that the resistor member 31 is formed on the second bonding pad 22 of the semiconductor chip 20, it is conceivable that the resistor member 31 may be formed on the second connection pad 12 of the printed circuit board 10.

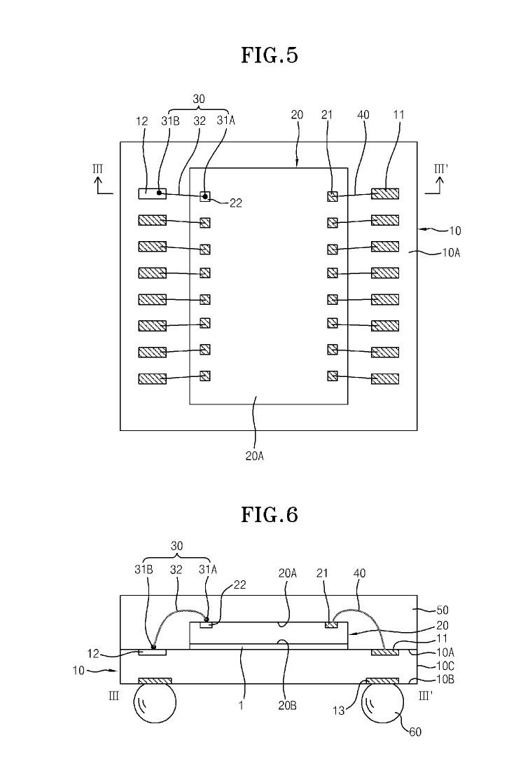

FIG. 5 is a plan view illustrating a semiconductor device in accordance with another exemplary embodiment of the present invention, and FIG. 6 is a cross-sectional view taken along the line III-III′ of FIG. 5.

The semiconductor device in accordance with this exemplary embodiment of the present invention has substantially the same construction as the semiconductor device in accordance with the exemplary embodiment described above with reference to FIGS. 1 and 2, except a resistor module 30. Accordingly, repeated descriptions for the same component elements will be omitted herein, and the same technical terms and the same reference numerals will be used to refer to the same component elements.

Referring to FIGS. 5 and 6, the semiconductor device in accordance with this exemplary embodiment of the present invention includes a printed circuit board 10, a semiconductor chip 20, and a resistor module 30. In addition, the semiconductor device may further include connection parts 40, a mold part 50 and external connection terminals 60.

In this exemplary embodiment, the resistor module 30 includes first and second resistor members 31A and 31B and a connection member 32.

The first resistor member 31A is formed on a second bonding pad 22 of the semiconductor chip 20, and the second resistor member 31B is formed on a second connection pad 12 of the printed circuit board 10. In this exemplary embodiment, the first and second resistor members 31A and 31B are formed as bumps or solder balls. The connection member 32 electrically connects the first resistor member 31A and the second resistor member 31B. In this exemplary embodiment, the connection member 32 is formed as a wire. The connection member 32 may be formed of the same material as the connection parts 40. For example, the connection member 32 may include at least any one selected from the group consisting of gold (Au), silver (Ag) and aluminum (Al).

The first and second resistor members 31A and 31B are formed of a material which has specific resistance larger than that of the connection parts 40 and the connection member 32. For example, the first and second resistor members 31A and 31B may include at least any one selected from the group consisting of manganese (Mn), tin (Sn) and titanium (Ti).

The resistance value of the resistor module 30 may be controlled by changing the diameter of the bumps or the solder balls constituting the first and second resistor members 31A and 31B. In the case where the resistor module 30 should have a large resistance value, the bumps or the solder balls constituting the first and second resistor members 31A and 31B are formed to have a relatively small diameter. In the case where the resistor module 30 should have a small resistance value, the bumps or the solder balls constituting the first and second resistor members 31A and 31B are formed to have a relatively large diameter.

It was illustrated and explained in this exemplary embodiment that the first and second resistor members 31A and 31B respectively contact the second bonding pad 22 of the semiconductor chip 20 and the second connection pad 12 of the printed circuit board 10, and are electrically connected with each other by the connection member 32. However, it is conceivable that connection members may respectively contact the second bonding pad 22 of the semiconductor chip 20 and the second connection pad 12 of the printed circuit board 10, and the connection member contacting the second bonding pad 22 of the semiconductor chip 20 and the connection member contacting the second connection pad 12 of the printed circuit board 10 may be electrically connected with each other by a resistor member.

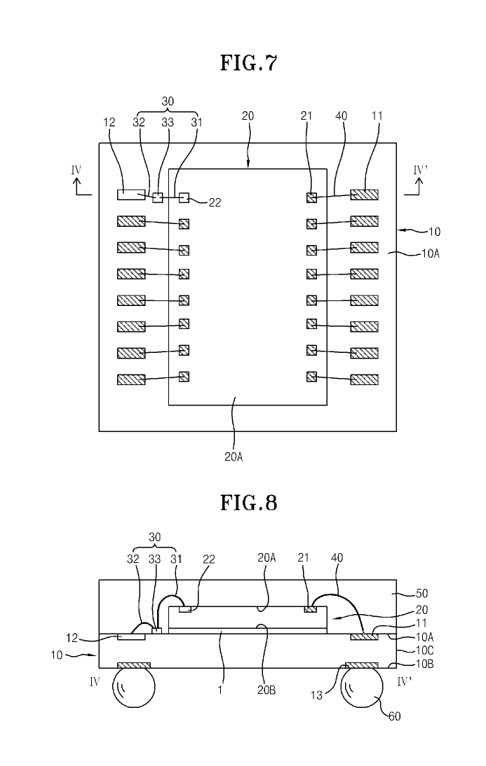

FIG. 7 is a plan view illustrating a semiconductor device in accordance with another exemplary embodiment of the present invention, and FIG. 8 is a cross-sectional view taken along the line IV-IV′ of FIG. 7.

The semiconductor device in accordance with this exemplary embodiment of the present invention has substantially the same construction as the semiconductor device in accordance with the exemplary embodiment described above with reference to FIGS. 1 and 2, except a resistor module 30. Accordingly, repeated descriptions for the same component elements will be omitted herein, and the same technical terms and the same reference numerals will be used to refer to the same component elements.

Referring to FIGS. 7 and 8, the semiconductor device in accordance with this exemplary embodiment of the present invention includes a printed circuit board 10, a semiconductor chip 20, and a resistor module 30. In addition, the semiconductor device may further include connection parts 40, a mold part 50 and external connection terminals 60.

In this exemplary embodiment, the resistor module 30 includes a resistor member 31, a connection member 32 and a connection pad 33.

The connection pad 33 is formed on a first surface 10A of the printed circuit board 10 outside the semiconductor chip 20. In this exemplary embodiment, the connection pad 33 is formed between a second connection pad 12 of the printed circuit board 10 and a second bonding pad 22 of the semiconductor chip 20.

The resistor member 31 electrically connects the second bonding pad 22 of the semiconductor chip 20 and the connection pad 33, and the connection member 32 electrically connects the connection pad 33 and the second connection pad 12 of the printed circuit board 10. In this exemplary embodiment, the resistor member 31 and the connection member 32 are formed as wires.

The connection member 32 may be formed of the same material as the connection parts 40. For example, the connection member 32 may include at least any one selected from the group consisting of gold (Au), silver (Ag) and aluminum (Al).

The resistor member 31 is formed of a material which has specific resistance larger than that of the connection parts 40 and the connection member 32. For example, the resistor member 31 may include at least any one selected from the group consisting of manganese (Mn), tin (Sn) and titanium (Ti).

The resistance value of the resistor module 30 may be controlled by changing the diameter and the length of the wire constituting the resistor member 31. In the case where the resistor module 30 should have a large resistance value, the wire constituting the resistor member 31 is formed to have a relatively small diameter or long length. In the case where the resistor module 30 should have a small resistance value, the wire constituting the resistor member 31 is formed to have a relatively large diameter or short length.

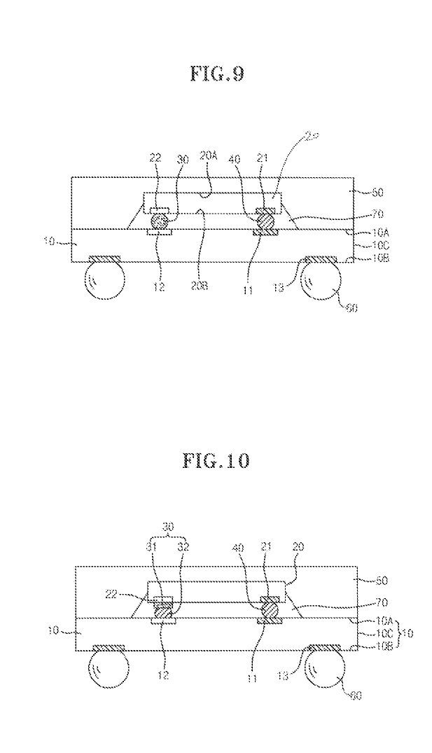

FIG. 9 is a cross-sectional view illustrating a semiconductor device in accordance with another exemplary embodiment of the present invention.

Referring to FIG. 9, the semiconductor device in accordance with this exemplary embodiment of the present invention includes a printed circuit board 10, a semiconductor chip 20, and a resistor module 30. In addition, the semiconductor device may further include connection parts 40, a mold part 50, external connection terminals 60, and an underfill member 70.

The printed circuit board 10 has a first surface 10A, a second surface 10B, and side surfaces 10C. The first surface 10A faces away from the second surface 10B, and the side surfaces 10C connect the first surface 10A and the second surface 10B.

The printed circuit board 10 includes first and second connection pads 11 and 12 and ball lands 13. The first and second connection pads 11 and 12 are formed on the first surface 10A of the printed circuit board 10, and the ball lands 13 are formed on the second surface 10B of the printed circuit board 10. While not shown in a drawing, the printed circuit board 10 may include circuit wiring lines which are formed on multiple layers in the printed circuit board 10 and conductive vias which connect the circuit wiring lines formed on different layers. The first and second connection pads 11 and 12 are electrically connected with the ball lands 13 by the circuit wiring lines and the conductive vias which are formed in the printed circuit board 10. The printed circuit board 10 may include any one selected among a module substrate, a package substrate, a main board, and a flexible substrate.

The semiconductor chip 20 has a third surface 20A which faces away from the first surface 10A of the printed circuit board 10 and a fourth surface 20B which faces away from the third surface 20A. First bonding pads 21 and a second bonding pad 22 are formed on the fourth surface 20B of the semiconductor chip 20. In this exemplary embodiment, the first bonding pads 21 are formed to face the first connection pads 11 of the printed circuit board 10, and the second bonding pad 22 is formed to face the second connection pad 12 of the printed circuit board 10. The semiconductor chip 20 may include any one selected among an image sensor, a memory semiconductor, a system semiconductor, a passive device, an active device, and a sensor semiconductor.

The resistor module 30 electrically connects the second connection pad 12 and the second bonding pad 22, and the connection parts 40 electrically connect the first connection pads 11 and the first bonding pads 21. In this exemplary embodiment, the resistor module 30 and the connection parts 40 are formed as bumps or solder balls.

The connection parts 40 may include at least any one selected from the group consisting of gold (Au), silver (Ag) and aluminum (Al).

In this exemplary embodiment, the resistor module 30 is formed of a resistor member which has specific resistance larger than that of the connection parts 40. For example, the resistor module 30 may include at least any one selected from the group consisting of manganese (Mn), tin (Sn) and titanium (Ti).

The underfill member 70 is filled between the printed circuit board 10 and the semiconductor chip 20, and the mold part 50 seals the first surface 10A of the printed circuit board 10 including the semiconductor chip 20. Further, the external connection terminals 60 are mounted to the ball lands 13 which are formed on the second surface 10B of the printed circuit board 10.

FIG. 10 is a cross-sectional view illustrating a semiconductor device in accordance with another exemplary embodiment of the present invention.

The semiconductor device in accordance with this exemplary embodiment of the present invention has substantially the same construction as the semiconductor device in accordance with the exemplary embodiment described above with reference to FIG. 9, except a resistor module 30. Accordingly, repeated descriptions for the same component elements will be omitted herein, and the same technical terms and the same reference numerals will be used to refer to the same component elements.

Referring to FIG. 10, the semiconductor device in accordance with this exemplary embodiment of the present invention includes a printed circuit board 10, a semiconductor chip 20, and a resistor module 30. In addition, the semiconductor device may further include connection parts 40, a mold part 50 and external connection terminals 60.

In this exemplary embodiment, the resistor module 30 includes a resistor member 31 and a connection member 32.

The resistor member 31 is formed on a second bonding pad 22 of the semiconductor chip 20. In this exemplary embodiment, the resistor member 31 is formed as a stud bump. The connection member 32 electrically connects the resistor member 31 and a second connection pad 12 of the printed circuit board 10. In this exemplary embodiment, the connection member 32 is formed as a bump or a solder ball. The connection member 32 may include at least any one selected from the group consisting of gold (Au), silver (Ag) and aluminum (Al).

The resistor member 31 is formed of a material which has specific resistance larger than that of the connection parts 40 and the connection member 32. For example, the resistor member 31 may include at least any one selected from the group consisting of manganese (Mn), tin (Sn) and titanium (Ti).

The resistance value of the resistor module 30 may be controlled by changing the height of the resistor member 31. In the case where the resistor module 30 should have a large resistance value, the resistor member 31 is formed to have a relatively large height. In the case where the resistor module 30 should have a small resistance value, the resistor member 31 is formed to have a small height.

Although it was illustrated and explained in this exemplary embodiment that the resistor member 31 is formed on the second bonding pad 22 of the semiconductor chip 20, it is conceivable that the resistor member 31 may be formed on the second connection pad 12 of the printed circuit board 10.

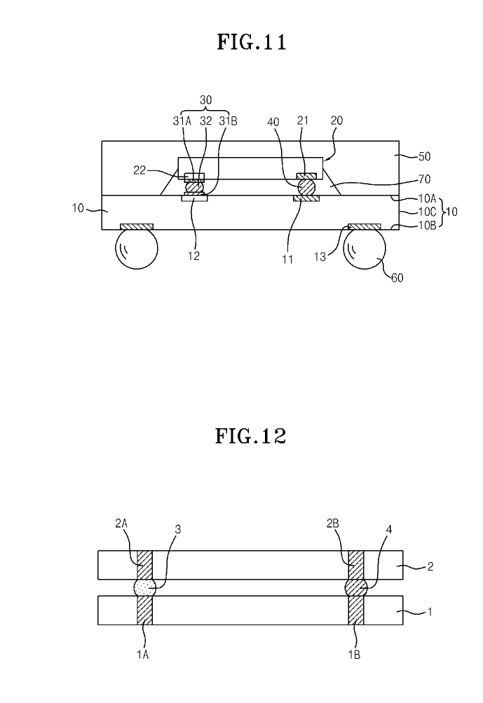

FIG. 11 is a cross-sectional view illustrating a semiconductor device in accordance with another exemplary embodiment of the present invention.

The semiconductor device in accordance with this exemplary embodiment of the present invention has substantially the same construction as the semiconductor device in accordance with the exemplary embodiment described above with reference to FIG. 9, except a resistor module 30. Accordingly, repeated descriptions for the same component elements will be omitted herein, and the same technical terms and the same reference numerals will be used to refer to the same component elements.

Referring to FIG. 11, the semiconductor device in accordance with this exemplary embodiment of the present invention includes a printed circuit board 10, a semiconductor chip 20, and a resistor module 30. In addition, the semiconductor device may further include connection parts 40, a mold part 50 and external connection terminals 60.

In this exemplary embodiment, the resistor module 30 includes first and second resistor members 31A and 31B and a connection member 32.

The first resistor member 31A is formed on a second bonding pad 22 of the semiconductor chip 20, and the second resistor member 31B is formed on a second connection pad 12 of the printed circuit board 10. In this exemplary embodiment, the first and second resistor members 31A and 31B are formed as stud bumps. The connection member 32 electrically connects the first resistor member 31A and the second resistor member 31B. In this exemplary embodiment, the connection member 32 is formed as a bump or a solder ball. For example, the connection member 32 may include at least any one selected from the group consisting of gold (Au), silver (Ag) and aluminum (Al).

The first and second resistor members 31A and 31B are formed of a material which has specific resistance larger than that of the connection parts 40 and the connection member 32. For example, the first and second resistor members 31A and 31B may include at least any one selected from the group consisting of manganese (Mn), tin (Sn) and titanium (Ti).

The resistance value of the resistor module 30 may be controlled by changing the height of the first and second resistor members 31A and 31B. In the case where the resistor module 30 should have a large resistance value, the first and second resistor members 31A and 31B are formed to have a relatively large height. In the case where the resistor module 30 should have a small resistance value, the first and second resistor members 31A and 31B are formed to have a relatively small height.

It was illustrated and explained in this exemplary embodiment that the first and second resistor members 31A and 31B respectively contact the second bonding pad 22 of the semiconductor chip 20 and the second connection pad 12 of the printed circuit board 10, and are electrically connected with each other by the connection member 32. However, it is conceivable that connection members may respectively contact the second bonding pads 22 of the semiconductor chip 20 and the second connection pad 12 of the printed circuit board 10, and the connection member contacting the second bonding pad 22 of the semiconductor chip 20 and the connection member contacting the second connection pad 12 of the printed circuit board 10 may be electrically connected with each other by a resistor member.

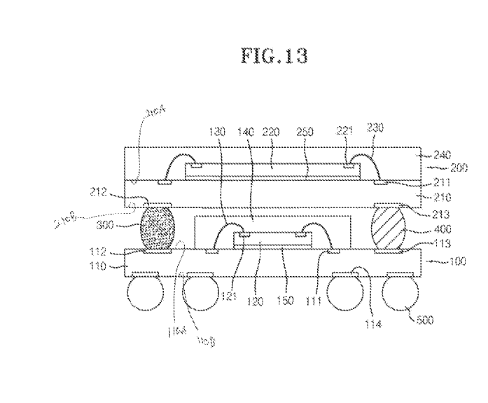

FIG. 12 is a cross-sectional view illustrating a semiconductor device in accordance with another exemplary embodiment of the present invention.

Referring to FIG. 12, the semiconductor device in accordance with this exemplary embodiment of the present invention includes first and second semiconductor chips 1 and 2, and a resistor module 3. In addition, the semiconductor device further includes connection parts 4.

The first semiconductor chip 1 has a first through electrode 1A and second through electrodes 1B. The first and second through electrodes 1A and 1B pass through the first semiconductor chip 1. The second semiconductor chip 2 has a third through electrode 2A and fourth through electrodes 2B. The third through electrode 2A passes through the second semiconductor chip 2 at a position corresponding to the first through electrode 1A, and the fourth through electrodes 2B pass through the second semiconductor chip 2 at positions corresponding to the second through electrodes 1B. Each of the first and second semiconductor chips 1 and 2 may include any one selected among an image sensor, a memory semiconductor, a system semiconductor, a passive device, an active device, and a sensor semiconductor.

The resistor module 3 electrically connects the first through electrode 1A and the third through electrode 2A, and the connection parts 4 electrically connect the second through electrodes 1B and the fourth through electrodes 2B. In this exemplary embodiment, the resistor module 3 and the connection parts 4 are formed as bumps or solder balls.

The connection parts 4 may include at least any one selected from the group consisting of gold (Au), silver (Ag) and aluminum (Al). The resistor module 3 is formed of a resistor member which has specific resistance larger than that of the connection parts 4. For example, the resistor module 3 may include at least any one selected from the group consisting of manganese (Mn), tin (Sn) and titanium (Ti).

Although it was illustrated and explained in this exemplary embodiment that the resistor module 3 is constituted by the resistor member which is connected between the first through electrode 1A and the third through electrode 2A, it is conceivable that the resistor member of the resistor module 3 may be formed in a partial space between the first through electrode 1A and the third through electrode 2A, i.e., as a portion of the resistor module 3, and a connection member may be additionally formed in the other space between the first through electrode 1A and the third through electrode 2A, i.e., as another portion of the resistor module 3. For example, the resistor member may be formed on the first through electrode 1A, and a connection member may be formed between the resistor member and the third through electrode 2A.

FIG. 13 is a cross-sectional view illustrating a semiconductor device in accordance with another exemplary embodiment of the present invention.

Referring to FIG. 13, the semiconductor device in accordance with this exemplary embodiment of the present invention includes a lower semiconductor package 100, an upper semiconductor package 200, and a resistor module 300. In addition, the semiconductor device further includes connection parts 400 and external connection terminals 500.

The lower semiconductor package 100 includes a first substrate 110, a first semiconductor chip 120, first bonding wires 130, and a mold part 140.

The first substrate 110 has a first surface 110A and a second surface 1106 which faces away from the first surface 110A, and includes first connection pads 111 and first, second and third ball lands 112, 113 and 114. The first connection pads 111 are formed on the first surface 110A, and the first and second ball lands 112 and 113 are formed on the first surface 110A outside the first connection pads 111. Further, the third ball lands 114 are formed on the second surface 1108. The first semiconductor chip 120 is attached, for example, in a face-up type to the first surface 110A of the first substrate 110 with an adhesive member 150 inside the first connection pads 111. The first bonding wires 130 electrically connect the first connection pads 111 of the first substrate 110 and bonding pads 121 of the first semiconductor chip 120. The mold part 140 is formed to seal the center portion of the first substrate 110 including the first semiconductor chip 120 and expose the first ball land 112.

The upper semiconductor package 200 includes a second substrate 210, a second semiconductor chip 220, second bonding wires 230, and a mold part 240.

The second substrate 210 has a third surface 210A and a fourth surface 210B which faces away from the third surface 210A, and includes second connection pads 211 and fourth and fifth ball lands 212 and 213. The second connection pads 211 are formed on the third surface 210A, and the fourth and fifth ball lands 212 and 213 are formed on the fourth surface 210B. The fourth ball land 212 corresponds to the first ball land 112 of the first substrate 110, and the fifth ball lands 213 correspond to the second ball lands 113 of the first substrate 110.

The second semiconductor chip 220 is attached, for example, in a face-up type to the third surface 210A of the second substrate 210 with an adhesive member 250 inside the second connection pads 211. The second bonding wires 230 electrically connect the second connection pads 211 of the second substrate 210 and bonding pads 221 of the second semiconductor chip 220, and the mold part 240 seals the second substrate 210 including the second semiconductor chip 220.

The resistor module 300 includes a resistor member which electrically connects the first ball land 112 of the first substrate 110 and the fourth ball land 212 of the second substrate 210, and the connection parts 400 include connection members which electrically connect the second ball lands 113 of the first substrate 110 and the fifth ball lands 213 of the second substrate 210. In this exemplary embodiment, the resistor module 300 and the connection parts 400 include solder balls.

The connection parts 400 may include at least any one selected from the group consisting of gold (Au), silver (Ag) and aluminum (Al). In this exemplary embodiment, the resistor module 300 is formed of a resistor member which has specific resistance larger than that of the connection parts 400. For example, the resistor module 300 may include at least any one selected from the group consisting of manganese (Mn), tin (Sn) and titanium (Ti).

Although it was illustrated and explained in this exemplary embodiment that the resistor module 300 is constituted by the resistor member which is electrically connected between the first ball land 112 and the fourth ball land 212, it is conceivable that the resistor member of the resistor module 300 may be formed in a partial space between the first ball land 112 and the fourth ball land 212, i.e., as a portion of the resistor module 300, and a connection member may be additionally formed in the other space between the first ball land 112 and the fourth ball land 212, i.e., as another portion of the resistor module 300. For example, the resistor member may be formed only on the first ball land 112, and a connection member may be formed between the resistor member and the fourth ball land 212.

As is apparent from the above description, the manufacture of a resistor-embedded semiconductor device can be easily implemented, and the reliability of the resistor-embedded semiconductor device can be improved.

Although specific exemplary embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A semiconductor package comprising:
a substrate including a substrate body which has an upper surface and a lower surface facing away from the upper surface, first connection pads which are formed on the upper surface, and a second connection pad which is formed on the upper surface to be separated from the first connection pads;
a semiconductor chip including first bonding pads and a second bonding pad;
connection members connecting the first connection pads and the first bonding pads; and
a resistor member connecting the second connection pad and the second bonding pad.

2. The semiconductor package according to claim 1, wherein the resistor member and the connection members are formed as bonding wires.

3. The semiconductor package according to claim 1, wherein the resistor member and the connection members are formed as bumps.

4. A semiconductor package comprising:
a substrate including a substrate body which has an upper surface and a lower surface facing away from the upper surface, first connection pads which are formed on the upper surface, and a second connection pad which is formed on the upper surface to be separated from the first connection pads;
a semiconductor chip including first bonding pads and a second bonding pad;
first connection members connecting the first connection pads and the first bonding pads;
a first resistor member formed on the second connection pad;
a second resistor member formed on the second bonding pad; and
a second connection member connecting the first resistor member and the second resistor member.

5. The semiconductor package according to claim 4, wherein the first resistor member and the second resistor member are formed as bumps.

6. The semiconductor package according to claim 4, wherein the first and second connection members are formed as bonding wires.

7. A semiconductor device comprising:
a first structural body having a first electrode pad;
a second structural body having a second electrode pad; and
a resistor module electrically connecting the first electrode pad and the second electrode pad and including a resistor member formed in at least a portion of the resistor module.

8. The semiconductor device according to claim 7, wherein each of the first structural body and the second structural body comprises any one of a semiconductor device, a printed circuit board and a semiconductor package.

9. The semiconductor device according to claim 8, wherein the semiconductor device comprises any one selected among an image sensor, a memory semiconductor, a system semiconductor, a passive device, an active device, and a sensor semiconductor.

10. The semiconductor device according to claim 8, wherein the printed circuit board comprises any one selected among a module substrate, a package substrate, a main board, and a flexible substrate.

11. The semiconductor device according to claim 7, wherein the resistor member comprises at least any one selected from the group consisting of manganese (Mn), tin (Sn) and titanium (Ti).

12. The semiconductor device according to claim 7, wherein the resistor module further includes a connection member which is formed in another portion of the resistor member and has specific resistance smaller than that of the resistor member.

13. The semiconductor device according to claim 12, wherein each of the connection member and the resistor member comprises any one selected among a wire, a bump, and a solder ball.

14. The semiconductor device according to claim 12, wherein the connection member comprises at least any one selected from the group consisting of gold (Au), silver (Ag) and aluminum (Al).

15. The semiconductor device according to claim 12, wherein the resistor member is formed on the first electrode pad, and the connection member electrically connects the resistor member and the second electrode pad.

16. The semiconductor device according to claim 12, wherein the resistor member is formed on the second electrode pad, and the connection member electrically connects the resistor member and the first electrode pad.

17. The semiconductor device according to claim 12, wherein the resistor member comprises a first resistor member which is formed on the first electrode pad and a second resistor member which is formed on the second electrode pad, and the connection member electrically connects the first resistor member and the second resistor member.

18. The semiconductor device according to claim 12, wherein the resistor module further includes a connection pad which is formed on the first structural body or the second structural body, the connection member electrically connects the first electrode pad and the connection pad, and the resistor member electrically connects the connection pad and the second electrode pad.

19. The semiconductor device according to claim 12, wherein the resistor module further includes a connection pad which is formed on the first structural body or the second structural body, the resistor member electrically connects the first electrode pad and the connection pad, and the connection member electrically connects the connection pad and the second electrode pad.

20. The semiconductor device according to claim 12, wherein the connection member comprises a first connection member which is formed on the first electrode pad and a second connection member which is formed on the second electrode pad, and the resistor member electrically connects the first connection member and the second connection member.
